(19) United States
(12) Patent Application Publication
(10) Pub. No.: US 2008/0135917 A1
(43) Pub. Date: Jun. 12, 2008

(54) METHOD TO FORM UNIFORM TUNNEL OXIDE FOR FLASH DEVICES AND THE RESULTING STRUCTURES

(76) Inventors: Zhong Dong, Fremont, CA (US); Chiliang Chen, Sunnyvale, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/608,702

(22) Filed: Dec. 8, 2006

(51) Int. Cl. H01L 29/788; H01L 21/31; H01L 23/58

(52) U.S. Cl. 257/321; 438/774; 257/632; 257/E23.002; 257/E29.3; 257/E21.24

(57) ABSTRACT

Thin oxide films are grown on silicon which has been previously treated with a gaseous or liquid source of chloride ions. The resulting oxide is of more uniform thickness than obtained on untreated silicon, thereby allowing a given charge to be stored on a floating gate formed over said oxide for a longer time than previously required for a structure not so treated.

### BACKGROUND

1. Field of the Invention

The present invention relates generally to methods of growing oxide films on silicon, and more particularly to methods of growing tunnel oxide films of highly uniform thickness on uneven silicon surfaces for improved uniformity.

2. Related Art

Many silicon devices, such as flash memory, require the growth of a thin oxide layer known as a tunneling oxide for use in a floating gate transistor, which is a component of the memory. For example, in flash memory, this oxide layer is grown on exposed areas of a silicon substrate, and separates the active area of silicon from a subsequent layer of polysilicon which, in a flash memory, functions as a floating gate on which charge can be stored. Such oxide layers may be on the order of 100 Å or less. A standard approach to the growth of oxide layers consists of a pre-cleaning, followed by an oxidation growth of the layer, followed by annealing. Depending on the pre-cleaning process, the silicon surface may be in a hydrophobic or a hydrophilic state.

One example of pre-cleaning, commonly used in the silicon semiconductor device fabrication industry, is the RCA cleaning method, but other cleaning methods are known in the art as well. The RCA process has three major sequential steps, consisting of (1) removal of insoluble organic contaminants with an aqueous solution of H₂O₂ and NH₄OH, (2) an oxide layer removal using a dilute aqueous solution of HF, and (3) removal of ionic and heavy atomic contaminants using an aqueous solution of H₂O₂ and HCl. The silicon wafer surface may be either hydrophobic or hydrophilic following this or equivalent cleaning procedures.

The oxidation growth process may be one of several available standard processes, such as thermal O₂, O₂ plus H₂, or O₂ plus HCl. This may be followed by either an in-situ or ex-situ anneal.

These standard procedures, however, are known to result in oxide thicknesses that may vary considerably over the silicon surface where the topography of the surface is made complex due to a succession of previous processes, such as, for example, shallow trench isolation (STI). This may be due, for instance, to oxides growing at corners where different crystallographic orientations are exposed, such as at the transition from the top surface of silicon to the sidewalls. Topographical features may also induce stress in the growth layers, resulting in uneven oxide growth rates. It is also known that the hydrophobic silicon surface is left with dangling silicon bonds following the pre-cleaning process, and this is considered to be a major factor in oxide layer growth, as will now be discussed.

FIGS. 1a(i and ii) illustrates an oxide layer growth process using prior art methods. Starting with a silicon (Si) substrate including a plurality of Si mesa 50, substantially isolated from each other by a high density plasma (HDP) 30 material, filled in the STI trench, in a first step, (FIG. 1A(i)), the substrate is pre-cleaned. In a second step (FIG. 1A(ii)), using well known oxide growth techniques, such as thermal oxidation, an oxide layer 60 is grown. It may often be the case that the resulting oxide layer 60 at the corners of the mesa-like silicon structure, indicated by arrows 10, is nearly twice as thick as at the center of the mesa, as indicated by arrows 20. If, for example, the surface of the silicon substrate has a <100> orientation, the edges of the mesa may present a <111> surface. Thus, the surface density of exposed silicon atoms—with their associated dangling bonds—is higher, and oxidation will proceed at a faster rate, resulting in thicker oxides at the edges, as observed. This will result in a significant increase in the distribution and magnitude of the threshold voltage required for tunneling current through the oxide, relative to the oxide thickness at the center of the mesa.

Accordingly, it is desirable to find a convenient method for treating the silicon surface in order to promote more uniform thin oxide growth.

### SUMMARY

In view of the above, an embodiment of the present invention provides a method for the substantially uniform growth of thin oxide layers on silicon surfaces of uneven topography and yields an oxide layer of more uniform thickness than in the prior art.

In accordance with this invention the silicon surface is treated prior to the growth of thermal oxide, to saturate the termination of dangling silicon bonds with chloride ions by means of liquid or dilute gaseous chemical processing. This treatment results in more uniform thickness of silicon dioxide formation on different silicon crystallographic orientations exposed as a result of etching processes which result in topographically complex silicon surfaces. It is believed that the chloride termination of the silicon bonds enhances oxygen diffusion to the oxide-silicon interface, leading to a faster oxidation rate. Additionally, it is believed that the chloride termination reduces the growth rate dependency on crystal orientation.

As a benefit of this invention, the mean value of the voltage on the control gate of a floating gate transistor required to erase data from the floating gate is lower than in prior art structures when the oxide layer of this invention is used between the floating gate and the underlying silicon substrate. Furthermore, the statistical variation of erasure voltage is reduced relative to the erasure voltage associated with floating gate structures using prior art methods of oxide growth. An additional benefit of this invention is to reduce charge trapping in the oxide layer, which results in longer memory retention of charge on the floating gate.

These and other features and advantages of the present invention will be more readily apparent from the detailed description of the embodiments set forth below taken in conjunction with the accompanying drawings.

### BRIEF DESCRIPTION OF THE FIGURES

FIGS. 1a(i and ii) illustrates an oxide layer growth process using prior art methods.

FIGS. 1b (i-iii) illustrates an oxide layer growth process according to one or more embodiments of the present invention.

FIG. 2 shows a flow chart for growing an oxide layer according to one or more embodiments of the invention.

FIG. 3 is a plot showing the charge trapping performance of an oxide layer grown in accordance with an embodiment of the present invention.

FIGS. 4a and 4b show, respectively, the statistical distribution of tunneling voltage for a block of floating gate transistors using prior art gate oxide, and the statistical distribution of tunneling voltage for a block of floating gate transistors using a new oxide layer grown in accordance with an embodiment of the present invention.

FIG. 4a shows the statistical distribution of tunneling voltage for a block of floating gate transistors using prior art gate oxide.

FIG. 4b shows the statistical distribution of tunneling voltage for a block of floating gate transistors using a new oxide layer grown in accordance with an embodiment of the present invention.

Like element numbers in different figures represent the same or similar elements.

### DETAILED DESCRIPTION

The following description is meant to be illustrative only and not limiting.

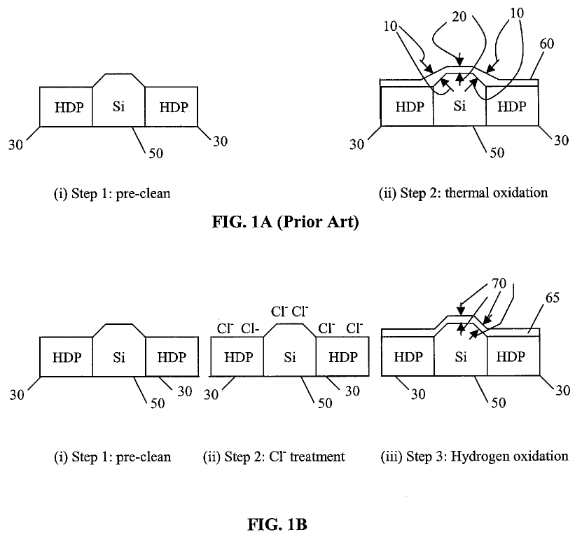

FIGS. 1B (i-iii) illustrates an oxide layer growth process according to one or more embodiments of the present invention. Starting with a silicon (Si) substrate including a plurality of Si mesa 50, substantially isolated from each other by a high density plasma (HDP) 30 material, filled in a STI trench, in a first step (FIG. 1B(i)), the substrate is pre-cleaned, using standard well known processes. In a second step (FIG. 1B(ii)), the substrate receives a chloride ion (Cl⁻) treatment in which the dangling bonds of Si atoms at the surface are terminated. In a third step (FIG. 1B(iii), a hydrogen-related process of chloride removal and gaseous oxide growth takes place, that produces an oxide layer 65 of uniform thickness over the exposed surface of Si mesa 50, as indicated by arrows 70. In accordance with one or more embodiments of the present invention, oxide growth methods to form gate oxides that may be used in floating gate transistors are described below where the resulting gate oxide has uniform thickness under the floating gate and over the channel region controlled by the floating gate.

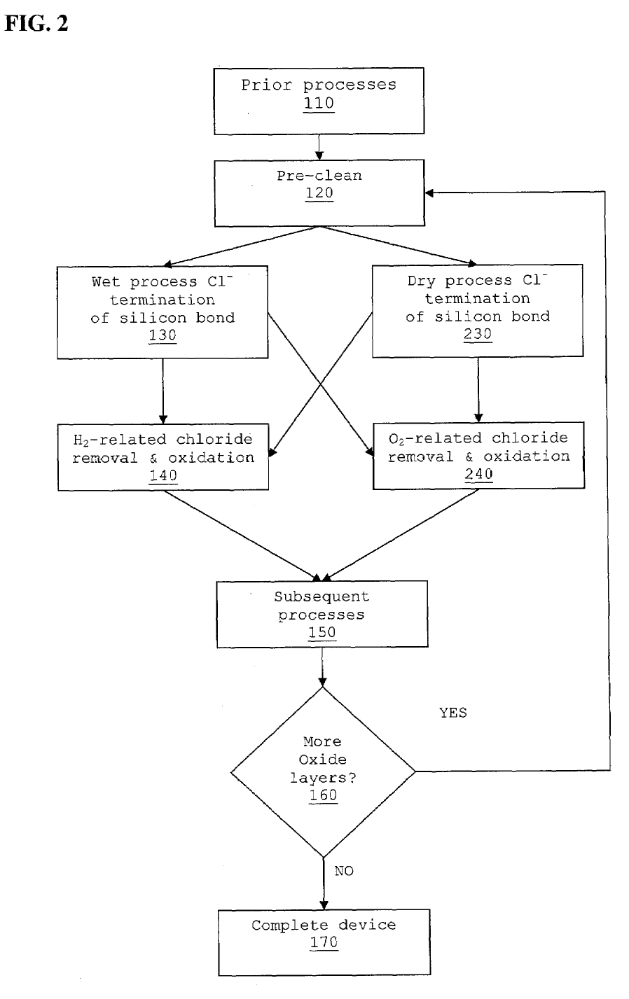

FIG. 2 illustrates schematically one embodiment of the oxide growth method 100 of this invention. After the silicon wafer is subjected to any prior process steps 110, the next step is a pre-clean 120 of the silicon substrate. Pre-clean step 120 may use any of the standard accepted methods for cleaning silicon, as described above. This may leave the substrate in a hydrophobic or a hydrophilic state. Hydrophilic silicon substrates may be less prone to attract contamination because a very thin oxide layer remains, which may also be less attractive to chloride ions. Therefore pre-cleaning 120 may also include additional process steps to remove the remnant oxide layer. Hydrophobic silicon substrates may be more attractive to contamination as well as chloride ions, so that pre-cleaning 120 may also include additional process steps to remove contamination in preparation for chloride bonding.

The process continues with two new steps:

First, a liquid chemical treatment for wet chloride termination 130 is used to terminate dangling silicon bonds. For example, a silicon wafer is dipped in a treatment solution comprising dilute aqueous hydrochloric acid and a limited amount of hydrogen peroxide (i.e., HCl in H₂O plus H₂O₂). In this step the concentration ratios may be in the range HCl:H₂O₂:H₂O=1:(0 to 1):(5 to 50) by volume. Only a small amount of H₂O₂ is required to assist in the dissociation of HCl to form chloride ions. Since only a very small amount of chloride is required, the H₂O₂ concentration is correspondingly small. The solution temperature is generally between 20° C. and 60° C., and the immersion time is from 10 sec to 10 min. Varying the range of listed parameters may have expected results, e.g., a higher temperature usually results in a shorter immersion time, and a higher concentration of HCl usually results in shorter immersion times at a given temperature.

Alternatively, chloride termination 130 of dangling silicon bonds may be achieved using 1,1,1-trichloroethane (TCA) or 1,2-dichloroethylene (Trans-LC, or TCL), solvents that may be commonly used in semiconductor processes. Either solvent, in vapor form may be transported through the reaction chamber by an inert carrier gas, for example, nitrogen or argon, using a bubbler method, to react in situ with a controlled amount of oxygen to form chloride ions. Typical partial pressure of the solvent gas is the partial vapor pressure of the solvent in liquid form at its corresponding temperature, which is typically ambient, but may vary.

Alternatively, dilute gaseous chloride termination step 230 can be used to terminate dangling silicon bonds. One exemplary gaseous chloride termination step 230 may include parameters selected from a gas mixture of HCl:O₂:N₂=1:(0 to 10):(5 to 10) by volume. As with the liquid treatment, above, gaseous oxygen (replacing peroxide) may react at high temperature to assist dissociation of HCl to form chloride ions in the gas phase, and the demand for oxygen ions may be low, so that the concentration of oxygen required may be correspondingly lower. The process temperature may range from 300° C. to 850 C, and a processing time of 10 sec to 10 min. Gas flow rates depend on the size of the process chamber and the number of silicon wafers (i.e., the surface area being processed), but may be about 10 standard liters/minute (slm) total for all gases.

If required, to remove any contaminants such as hydrocarbons, the wafer is then removed and rinsed, then dried using, for example, standard accepted semiconductor handling procedures such as deionized water rinsing, followed by spin drying or solvent vapor (e.g., isopropyl alcohol vapor (IPA)) drying.

Third, a hydrogen-related process of chloride removal and gaseous oxide growth 140 is used to promote growth of silicon dioxide (SiO₂). This process also provides for the removal of chloride prior to promoting oxide growth. Two types of gaseous hydrogen-related oxide growth processes 140 can be used: a hydrogen-dominated process, or an oxygen-dominated process, described below.

The hydrogen-dominated process consists essentially of thermal H₂+O₂+N₂ (or AR), where the gas mixture is in the range H₂:O₂:N₂ (or Ar)=1:(0.46 to 5):(0 to 10) by volume, at a temperature between 600 C and 1100 C, and a processing time of 10 sec to 1 hour.

An alternative oxygen-dominated process of chloride removal and gaseous oxide growth process 240 may have a gas mixture selected from the range H₂:O₂:N₂ (or Ar)=1:(3 to 100):(0 to 100) by volume, at a temperature between 600 C and 1100 C, and a processing time of 10 sec to 1 hour. Introducing nitrogen usually reduces the oxide growth rate, as will lowering temperature.

Alternatively, a steam oxide growth step 240, such as In-Situ Steam Generation (ISSG), may be used in lieu of the hydrogen-related oxidation. ISSG is a process well known in the art. A hydrogen-lean mixture with oxygen (where an approximate ratio may be, for example, 0.01:1 by volume) is transported into a cold wall chamber. The gas flows over silicon wafers maintained at a typical exemplary temperature of approximately 1100° C. where the gases react near the heated wafer surface to form steam and atomic oxygen. The atomic oxygen then reacts with silicon to grow the oxide layer. The leanness of the mixture controls the growth rate. This method is advantageous for accurately controlling growth of thin oxide layers.

In the above described oxide growth processes, parameters may be varied to obtain oxide layers in the range of 50 to 100 Å.

The silicon wafer then advances to subsequent conventional processes 150. At some point in the process it may be required to grow more oxide layers using the same novel steps as described above, namely chloride termination 130 and oxide growth 140. If this is required, then the method repeats the steps of pre-clean 120 (as needed), chloride termination 130/230, oxide growth 140/240, and subsequent processes 150 (as needed). When all such process steps are satisfactorily completed, the silicon wafer proceeds to device completion 170.

Notice that wet chloride termination step 130 can be used with a vapor oxide growth step 240 or, alternatively, vapor phase chloride termination step 230 can be used with wet oxide growth step 140. Any intermediate cleaning and rinsing procedures required to proceed from one step (130 or 230) to another (140 or 240) are inherent in oxide growth method 100.

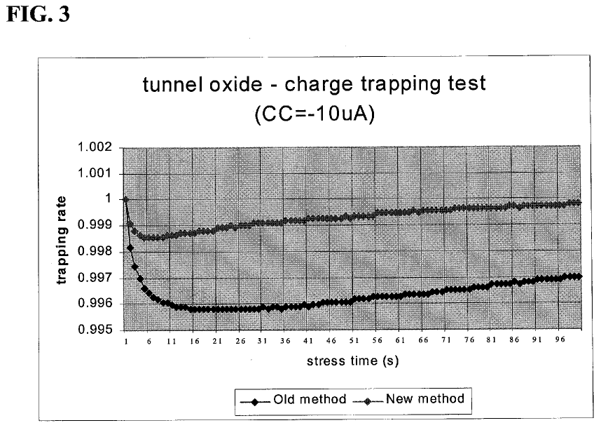

Referring to FIG. 3, improvement is demonstrated in the quality of an oxide grown in accordance with one embodiment of the present invention. A voltage is applied variably to the control gate of a floating gate transistor to maintain a constant tunneling current through the oxide of a representative floating gate device. The tunneling current is not high enough to cause breakdown of the oxide over the duration of the test interval. Any charge trapped in the oxide may provide a means to conduct current at a lower voltage, in which case the trapping rate, i.e., the ratio V(t)/V(0) of the driving voltage V(t) to the initial voltage V(0) will drop, then slowly recover as trapped charges are swept out of the oxide. A smaller change in voltage V(t) means lower trapping rate and indicates that the oxide has a lower trap density, and is therefore of higher quality. A lower trap density has the benefit of providing a longer charge storage lifetime on the floating gate, meaning the memory is less volatile. The upper curve shows V(t)/V(0) for an oxide layer grown in accordance with one embodiment of the present invention. It shows a significantly smaller drop in driving voltage and quicker recovery to its initial value, which indicates a lower trap density in the oxide layer than is indicated by the lower curve, representative of an oxide layer grown with prior art methods.

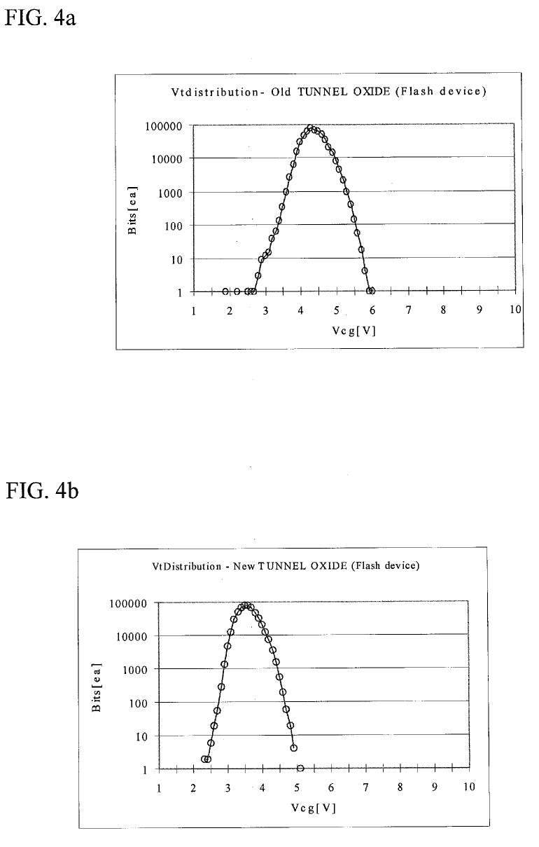

A further benefit can be seen by referring to FIGS. 4a and 4b. Both figures show the distribution of control gate voltages required to erase the stored charge for a large number of floating gate devices. Each bit refers to a single floating gate device. It is desirable for all devices to be erasable within a very narrow voltage range (ideally a single value). FIG. 4a shows the population distribution of devices made using a prior art method to grow the silicon oxide under the floating gate. As shown, these devices erase at different voltages. The mean is approximately 4.5 volts. In comparison, FIG. 4b shows the population distribution for devices made in accordance with an embodiment of the present invention. The mean erasure voltage is about 3.5 volts, which is beneficial for lower power requirements. Furthermore, the narrower distribution of the measured erasure voltages indicates that the oxide growth process is of higher uniformity than in the prior art (i.e., fewer devices are erasable at voltages with large offsets from the mean), which may result in fewer defective memory cells in a flash memory.

Following is a set of process steps setting forth a complete example of the method of forming a tunnel oxide for flash devices according to an embodiment of the present invention. Note that the example may contain more than one option for a given process step. Either option may be chosen in proceeding through the example process.

### EXAMPLE I

First Pre-clean process 120 was performed to prepare the silicon wafers for the subsequent steps. Specifically, wafers were immersed for 90 sec at 50° C. in a solution of H₂SO₄/H₂O₂ in a ratio, by volume of 600/145. The wafers were then rinsed with de-ionized water (DI) for 60 sec. Then followed wafer immersion for 250 sec at 40° C. in a solution of NH₄OH/H₂O₂/DI at a volume ratio of 125/125/1500. The wafers were then rinsed in DI for 60 sec. Next, the wafers were immersed for 110 sec at 50° C. in a solution of HCL/H₂O₂/DI volume at a volume ratio of 125/125/1500, followed by another DI rinse for 60 sec. Then the wafers were immersed for 3 min at 20° C. in a solution of HF/DI at a volume ratio of 30/1500, again followed by a DI rinse for 60 sec. Finally, the wafers were spin dried under hot blowing nitrogen gas. This cleaning process renders the wafer surface hydrophobic and ready for chloride treatment.

The next step was that of treating the silicon substrate with chloride ions to saturate the silicon dangling bonds. In chloride treatment process 130-1 wafers were immersed for 5 min @ 55° C. in a solution of HCl/H₂O₂/DI at a volume ratio of 125/12.5/1250, followed by a DI rinse for 3 min, followed by an isopropyl alcohol (IPA) vapor spray drying to displace water.

The process continued with removal of chloride ions and growth of the oxide. In the hydrogen-dominated process 140, the wafer temperature was ramped up to 780° C. at 10° C./min in N₂ flowing at 10 slm at 1 atm pressure. Chloride removal then proceeded for 2 min at 780° C. in a gas flow of H₂ at 5 slm, O₂ at 5 slm, and N₂ at 10 slm, at 1 atm pressure.

In preparation for oxide growth, the wafer temperature was first ramped up to 800° C. at 6° C./min in a gas flow of N₂ at 10 slm, at 1 atm pressure, and stabilized for 5 min at temperature. Oxide growth proceeded with a gas flow of H₂ at 5 slm, O₂ at 4 slm, N₂ at 9 slm, and TCA at 200 sccm for approximately 16 min. When the target oxide thickness of 90 Å+/−5 Å was reached, the chamber temperature was ramped up to 850° C. in N₂ flowing at 10 slm at 1 atm at 5° C./min, which took approximately 10 min. The wafers were then annealed for 15 min at 850° C. in N₂ at 10 slm, at a pressure of 1 atm. Temperature was ramped down at 8° C./min to a target temperature of 600° C. in N₂ at 10 slm, at 1 atm pressure.

Example I may be modified by substitution of certain process steps to achieve the same result.

As a modification of Example I, Example II, chloride treatment process 130-2 was used instead of chloride treatment process 130-1. The process step consisted of wafer immersion for 60 sec at 50° C. in a solution of HCl/H₂O₂/DI, volume ratio=125/12.5/1250, followed by DI rinse for 60 sec, followed by spin drying under hot nitrogen gas.

As a further modification to Example I, Example III, high temperature chloride vapor treatment process 230 was used instead of chloride treatment process 130-1. Specifically, wafers were placed in a chamber where the temperature was ramped up at 12° C./min to a target temperature of temp=800° C. in a N₂ environment at 1 atm pressure flowing at 10 slm.

At temperature, the wafers were treated for 5 min at 800° C. with a gas flow of TCA at 100 sccm (standard cubic cm/sec), i.e., chemical TCA was delivered to the furnace by carrier gas N₂, plus process N₂ gas flow at 10 slm, and O₂ at 10 sccm at 1 atm pressure. The temperature was then ramped down at 12° C./min to a target temperature of 300° C. in a gas flow of N₂ at 10 slm at 1 atm pressure.

As a further modification to Example I, Example IV, oxygen-dominated process 240 was used as process step to remove chloride and grow an oxide layer. Here, chloride removal began with a pressure ramp-down at 50 torr/sec to a target pressure of 10 torr in N₂ flowing at 10 slm, which took approximately 15 sec. Temperature was ramped up at 50° C./sec to a target temperature of 850° C., with N₂ flowing at 10 slm, and chamber pressure at 10 torr. This took approximately 13 sec. The oxygen-dominated oxide grow to remove chloride proceeded at 850° C. for 10 sec by introducing H₂ at 0.1 slm, and O₂ at 10 slm, maintaining pressure 10 torr. Temperature was then ramped up to 1050° C. at 35° C./sec in approximately 8 sec, in N₂ at 10 slm and pressure of 10 torr. Oxide growth proceeded at 1050° C., pressure 10 torr, with H₂ gas flow at 0.2 slm, O₂ gas flow at 9.8 slm, for approximately 58 sec, to an oxide thickness of 70 Å+/−5 Å. Following the oxide growth step, annealing took place at 1050° C., a pressure of 10 torr of N₂ flowing at 10 slm for 15 sec, followed by a temperature ramp-down at 50° C./second in N₂ gas flowing at 10 slm at a pressure of 10 torr to a target temperature of 500° C., which took approximately 11 sec.

Having thus described embodiments of the present invention, persons of ordinary skill in the art will recognize that changes may be made in form and detail without departing from the scope of the invention. Thus the invention is limited only by the following claims.

What is claimed is:

1. A method of growing an oxide layer on a silicon substrate, comprising:
cleaning the substrate;
treating the substrate with chloride ions;
removing the chloride ions in-situ; and
growing an oxide layer on the substrate.

2. The method of claim 1, wherein the step of treating the substrate with a source of chloride ions further comprises:
treating the substrate with an aqueous solution of hydrogen chloride.

3. The method of claim 2, wherein the aqueous solution of hydrogen chloride comprises hydrogen chloride hydrogen peroxide and water, and wherein the concentrations by volume are in the ratios of 1 part hydrogen chloride, from 0 to 1 part hydrogen peroxide, and from 5 to 50 parts water.

4. The method of claim 2, wherein the temperature of the solution is from 20° C. to 60° C.

5. The method of claim 2, wherein the substrate is immersed in the solution between 10 sec and 10 min.

6. The method of claim 1, wherein the step of treating the substrate with chloride ions further comprises:
treating the substrate with an gas comprising hydrogen chloride.

7. The method of claim 6, wherein the gas is comprised of hydrogen chloride, oxygen and nitrogen, wherein the concentrations by volume are in the range 1 part hydrogen chloride, from 0 to 10 parts oxygen, and from 5 to 50 parts nitrogen.

8. The method of claim 6, wherein the treating is at a processing temperature from 300° C. to 850° C.

9. The method of claim 6, wherein the treating is for a processing time from 10 sec to 10 min.

10. The method of claim 1, wherein the step of treating the substrate with a source of chloride ions further comprises treating the substrate with a solvent 1,1,1-trichloroethane (TCA) or 1,2-dichloroethylene (Trans-LC, or TCL).

11. The method of claim 10, wherein the solvent is delivered to treat the substrate via gas bubbler transport in an inert gas including nitrogen or argon at partial vapor pressure at substantially ambient temperature.

12. The method of claim 1, wherein the step of growing an oxide layer further comprises treating the substrate with a gas comprising hydrogen.

13. The method of claim 12, wherein the gas further comprises hydrogen, oxygen, and nitrogen or argon, wherein the concentrations by volume flow rate are in the range 1 part hydrogen, from 0.46 to 5 parts oxygen, and from 0 to 10 parts nitrogen or argon.

14. The method of claim 12, wherein the gas further comprises hydrogen, oxygen, and nitrogen or argon, wherein the concentrations by volume flow rate are in the range 1 part hydrogen, from 3 to 100 parts oxygen, and from 0 to 100 parts nitrogen or argon.

15. The method of claim 12, wherein the processing temperature is from 600° C. to 1100° C.

16. The method of claim 12, wherein the processing time is from 10 sec to 1 hour.

17. The method of claim 1, wherein the step of growing an oxide layer further comprises treating the substrate by in-situ steam generation, wherein the gas further consists essentially of hydrogen, oxygen, wherein the concentration of hydrogen is between about 5% and 30%, and the reaction temperature at the substrate is between about 600° C. and 1100° C.

18. A silicon substrate having an oxide layer formed thereon, wherein said substrate has been treated by the method of claim 1.

19. The substrate of claim 18, wherein said oxide layer has a thickness selected to allow electrons to tunnel through said oxide to a floating gate.

20. The substrate of claim 18, wherein said oxide layer has a thickness less than 100 Å.

21. A floating gate transistor comprising:
a silicon substrate having a gate oxide formed thereon using the method of claim 1;
a floating gate formed on said oxide;
insulation formed on said floating gate; and
a control gate formed on said insulation, said control gate being capable of having a voltage applied thereto sufficient to cause charge to be stored on said floating gate.
